(19) United States
(12) Patent Application Publication
(10) Pub. No.: US 2025/0223693 A1
(43) Pub. Date: Jul. 10, 2025

(54) APPARATUS FOR MANUFACTURING SEMICONDUCTOR STRUCTURE AND METHOD FOR MANUFACTURING SEMICONDUCTOR STRUCTURE

(71) Applicant: TAIWAN SEMICONDUCTOR MANUFACTURING COMPANY LTD., HSINCHU (TW)

(72) Inventors: YU-SEN CHU, HSINCHU CITY (TW); MING-YAO HSIAO, TAICHUNG CITY (TW)

(21) Appl. No.: 18/403,785

(22) Filed: Jan. 4, 2024

(51) Int. Cl. C23C 16/44; C23C 16/455

(52) U.S. Cl. CPC C23C 16/4412; C23C 16/45527; C23C 16/45544

(57) ABSTRACT

An apparatus for manufacturing a semiconductor structure includes a trapping unit configured to collect chemicals discharged from a processing chamber; a cooling system disposed adjacent to the trapping unit and configured to cool the trapping unit; and a control system electrically connected to the cooling system, wherein the cooling system has a sensor for providing information to the control system, and the control system derives an estimated timing of replacing the trapping unit based on the information. A method for manufacturing a semiconductor structure includes providing a gas into a processing chamber; allowing the gas to react with the semiconductor structure within the processing chamber, wherein chemicals are generated during the reaction; discharging a residual gas and the chemicals from the processing chamber toward a first trapping unit through an exhaust conduit coupled to the processing chamber; and cooling the first trapping unit.

### BACKGROUND

Conventional atomic layer deposition (ALD) systems operate as a gas or vapor deposition system that can be used to deposit thin film material layers onto exposed surfaces of one or more substrates. More specifically, ALD is a thin film deposition technique which functions via sequential exposure of deposition substrates to multiple, distinct chemical and/or energetic environments. A typical process includes introduction of a vapor phase metal-atom-containing gas, which reacts with preexisting chemical moieties on surfaces of semiconductor structures, such as substrates, followed by a purge cycle to remove residual gas and chemicals generated during the aforementioned reaction.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a schematic view of an apparatus in accordance with some embodiments of the present disclosure.

FIG. 2 is a schematic top view of a portion of an apparatus according to aspects of the present disclosure in some embodiments.

FIG. 3 is an enlarged schematic cross-sectional view of a trapping unit of an apparatus in accordance with some embodiments of the present disclosure.

FIG. 4 is a flowchart of a method for manufacturing a semiconductor structure in accordance with some embodiments of the present disclosure.

FIG. 5 is a flowchart of a method for manufacturing a semiconductor structure in accordance with some embodiments of the present disclosure.

FIGS. 6 and 7 are cross-sectional views of one or more stages of a method of manufacturing a semiconductor structure in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies.

Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

During manufacture of semiconductor structures, objects, such as substrates, are placed inside a substantially sealed reaction chamber which is generally evacuated to a low deposition pressure. A precursor or reactant gas is introduced into the reaction chamber to react with exposed surfaces or coating surfaces of the semiconductor structures. An inert carrier gas may be mixed with the reactant gas during delivery of the reactant gas. Chemicals are generated during the reaction, and after a desired exposure time, the chemicals and a residual reactant gas are removed or purged from the reaction chamber. A purge cycle generally includes drawing the chemicals and the residual reactant gas from the reaction chamber through an exhaust conduit in communication with a vacuum pump.

A conventional ALD apparatus includes a trapping unit disposed between the exhaust conduit and the vacuum pump. The trapping unit traps the chemicals to prevent the chemicals from damaging the vacuum pump. If the ALD apparatus has no trapping unit, the chemicals and the residual reactant gas may contact internal surfaces of the exhaust conduits and the vacuum pump, ultimately leading to undesirable surface contamination and accumulation, and eventual vacuum pump failure.

While various trapping units are known for removing chemicals and the residual reactant gas from the outflow of the reaction chamber of the ALD apparatus, one particularly useful trapping unit conventionally used in the ALD apparatus comprises plates inside a trapping chamber, wherein the plates provide a large surface area on which the chemicals accumulate. When excessive amounts of the chemicals and the residual reactant gas accumulate in the trapping unit, the chemicals and the residual reactant gas become jammed in the trapping chamber and cannot be removed from the trapping unit to the vacuum pump. As a result, the residual reactant gas cannot be removed from the sealed reaction chamber, causing a pressure of the reaction chamber to be greatly increased to undesired levels. In order to remove the jammed trapping unit and replace it with a new trapping unit, the apparatus having the reaction chamber with the undesired pressure must be shut down. Further, a condition of the trapping unit is unpredictable, the trapping unit needs to be replaced with a new trapping unit after the reaction chamber reaches the undesired pressure, and semiconductor structures disposed in the reaction chamber may be adversely affected. Accordingly, an improved apparatus for manufacturing a semiconductor structure and an improved method for manufacturing a semiconductor structure are needed.

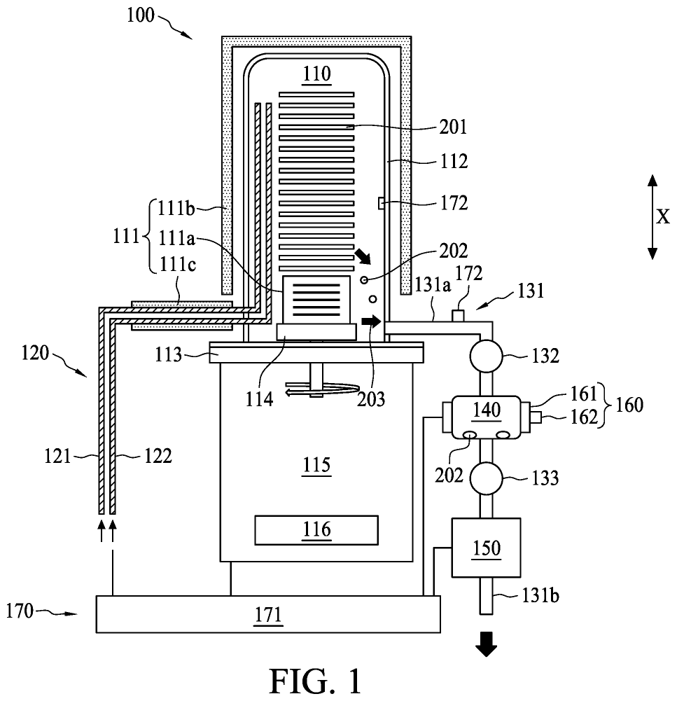

FIG. 1 is a schematic view of an apparatus 100 for manufacturing a semiconductor structure in accordance with some embodiments of the present disclosure. Referring to FIG. 1, the apparatus 100 for manufacturing a semiconductor structure 201 includes a processing chamber 110, a gas supply system 120, an exhaust conduit 131, a trapping unit 140, a cooling system 160 disposed adjacent to the trapping unit 140, and a pump 150.

In some embodiments, the processing chamber 110 is configured to form a film (not shown) on the semiconductor structure 201. In some embodiments, the semiconductor structure 201 is a wafer, such as a silicon wafer. In some embodiments, the semiconductor structure 201 includes a semiconductor substrate area. In some embodiments, the film is formed on the semiconductor substrate area. In some embodiments, the semiconductor substrate area is a bulk semiconductor, a semiconductor-on-insulator (SOI) substrate, or the like, and may be doped (e.g., with a p-type or n-type dopant) or undoped. Generally, an SOI substrate is comprised of a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate, may also be used. In some embodiments, the semiconductor material of the semiconductor substrate area includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or a combination thereof.

In some embodiments, the apparatus 100 is configured to form the film over the semiconductor structure 201 by an atomic layer deposition (ALD) process. Atomic layer deposition is a technique that allows growth of thin films, atomic layer by atomic layer, on the semiconductor structure 201. The technique can include, but is not limited to, deposition of titanium nitride (TiN) and ammonium chloride (NH₄Cl) from ammonia and titanium tetrachloride (TiCl4) precursors (6TiCl₄+32NH₃→6TiN+24NH₄Cl+N₂). Titanium tetrachloride (TiCl₄), which is a metal-containing gas such as a titanium (Ti)-containing gas, is supplied into the processing chamber 110 and serves as a source gas. When a liquid source that is in a liquid state under normal temperature and normal pressure, such as TiCl₄, is used, the liquid source is vaporized by a vaporizing system (not illustrated) such as a vaporizer or a bubbler and is then supplied as the gas. Ammonia (NH₃), which is a nitrogen-containing gas, is supplied into the processing chamber 110 and serves as a reaction gas that reacts with the source gas. Recipes for many other materials to produce insulators, metals and semiconductors, can be found in related literature.

In some embodiments, the apparatus 100 further includes a heating system 111 configured to heat the semiconductor structures 201 disposed in the processing chamber 110. In some embodiments, the heating system 111 includes a first heater 111a disposed under the semiconductor structures 201 and a second heater 111b disposed adjacent to the processing chamber 110. In some embodiments, the second heater 111b has a cylindrical shape having an upper end that is blocked. In some embodiments, the second heater 111b is concentrically provided with respect to the processing chamber 110.

In some embodiments, the processing chamber 110 is made of a heat-resistant material such as quartz (SiO2) or silicon carbide (SiC). In some embodiments, the processing chamber 110 includes a reaction tube 112 in a cylindrical shape having an upper end that is blocked and having a lower end that is open. In some embodiments, a seal cap 113 seals the lower end of the reaction tube 112 with an airtight closure. In some embodiments, the processing chamber 110 is defined by the reaction tube 112 and the seal cap 113. In some embodiments, a supporting device 114 is disposed in the processing chamber 110, and the first heater 111a and the semiconductor structures 201 are disposed on the supporting device 114. The supporting device 114 is configured to hold the semiconductor structures 201. In some embodiments, the supporting device 114 is rotatable.

In some embodiments, the semiconductor structure 201 is disposed in the processing chamber 110. In some embodiments, the semiconductor structure 201 is disposed on the first heater 111a and the supporting device 114. In some embodiments, a plurality of the semiconductor structures 201 are disposed in the processing chamber 110. In some embodiments, the plurality of the semiconductor structures 201 to be batch-processed are horizontally stacked on the supporting device 114 in an axis direction X of the reaction tube 112 in multiple stages.

In some embodiments, the apparatus 100 further includes a sensor 172 disposed in or adjacent to the processing chamber 110 and configured to detect a pressure of the processing chamber 110. In some embodiments, the sensor 172 is electrically connected to a control system 170 configured to control the apparatus 100, including controlling the gas supply system 120 and the cooling system 160. In some embodiments, the control system 170 is configured to control environmental conditions of the processing chamber 110 and is electrically connected to the gas supply system 120, the cooling system 160 and the pump 150. In some embodiments, the environmental conditions such as temperature, humidity, air flow rate, pressure, and amount of chemicals 202 in the processing chamber 110 are adjusted by the control system 170. In some embodiments, the control system 170 includes a central processor 171 and a plurality of sensors 172 disposed throughout the apparatus 100 and electrically connected to the central processor 171. In some embodiments, the sensors 172 provide information to the central processor 171, and the central processor 171 adjusts the environmental conditions in accordance with the information.

A number and locations of the plurality of sensors 172 are not particularly limited. For example, the sensors 172 can be arranged anywhere in the processing chamber 110 and spaced apart from each other, anywhere in the gas supply system 120 and spaced apart from each other, and anywhere in the exhaust conduit 131 and spaced apart from each other; however, the present invention is not limited thereto.

In some embodiments, the apparatus 100 further includes a wafer loading area 115 disposed under the processing chamber 110, and a nitrogen purge system 116 disposed in the wafer loading area 115. In some embodiments, the wafer loading area 115 surrounds the seal cap 113 and is filled with nitrogen gas.

In some embodiments, the gas supply system 120 is in communication with the processing chamber 110. In some embodiments, the gas supply system 120 includes a first gas conduit 121 configured to provide a first gas, such as the source gas, into the processing chamber 110, and a second gas conduit 122 configured to provide a second gas, such as the reaction gas, into the processing chamber 110. In some embodiments, one end of the first gas conduit 121 is installed in the processing chamber 110, and another end of the first gas conduit 121 is distal to the processing chamber 110 and configured to allow the first gas to enter into the first gas conduit 121. In some embodiments, one end of the second gas conduit 122 is installed in the processing chamber 110, and another end of the second gas conduit 122 is distal to the processing chamber 110 and configured to allow the second gas to enter into the second gas conduit 122. In some embodiments, a third heater 111c is disposed on the first gas conduit 121 and/or the second gas conduit 122 and is configured to heat the first gas and/or the second gas.

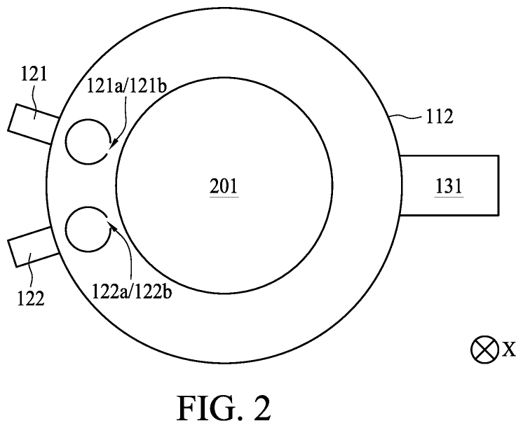

FIG. 2 is a schematic top view of a portion of the apparatus 100 for manufacturing a semiconductor structure shown in FIG. 1 in accordance with some embodiments of the present disclosure. Referring to FIGS. 1 and 2, the first gas conduit 121 includes a first nozzle 121a configured to supply the first gas toward the semiconductor structure 201. In some embodiments, the first nozzle 121a is installed along an arrangement region of a plurality of semiconductor structures 201 in which the semiconductor structure 201 is arranged. In some embodiments, the first nozzle 121a includes a plurality of openings 121b configured to deliver the first gas into the processing chamber 110, wherein the openings 121b are open toward a center of the processing chamber 110.

Similarity, in some embodiments, the second gas conduit 122 includes a second nozzle 122a configured to supply the second gas toward the semiconductor structure 201. In some embodiments, the second nozzle 122a is installed along the arrangement region of the plurality of semiconductor structures 201 in which the semiconductor structure 201 is arranged. In some embodiments, the second nozzle 122a includes a plurality of openings 122b configured to deliver the second gas into the processing chamber 110, wherein the openings 122b are open toward the center of the processing chamber 110.

In some embodiments, the first gas and the second gas are transferred into the processing chamber 110 through the first nozzle 121a and the second nozzle 122a, respectively. In the embodiment shown in FIGS. 1 and 2, the first gas and the second gas may be equally supplied to each semiconductor structure 201, thereby equalizing a film thickness of the film to be formed on each semiconductor structure 201. In some embodiments, the chemicals 202 and a residual gas 203 are generated in the processing chamber 110 after the first gas and the second gas react with the semiconductor structures 201. In some embodiments, the residual gas 203 includes unreacted first gas, unreacted second gas, and nitrogen gas.

In some embodiments, the exhaust conduit 131, coupled to the processing chamber 110, is configured to discharge the residual gas and chemicals from the processing chamber 110. In some embodiments, the exhaust conduit 131 has a first end 131a coupled to the processing chamber 110 and a second end 131b distal to the processing chamber 110. In some embodiments, as seen in a transverse cross-sectional view, the exhaust conduit 131 is disposed opposite to the gas supply system 120. In some embodiments, as seen in a longitudinal cross-sectional view, the exhaust conduit 131 is disposed below the first nozzle 121a and the second nozzle 122a.

In some embodiments, the exhaust conduit 131 comprises, connected sequentially from the first end 131a to the second end 131b, a first valve 132 serving as an exhaust valve, the trapping unit 140 configured to collect the chemicals 202 discharged from the processing chamber 110, and a pump 150 serving as a vacuum exhaust device.

In some embodiments, the first valve 132 is disposed inside the exhaust conduit 131 and between the processing chamber 110 and the trapping unit 140. In some embodiments, the first valve 132 is configured to control a flow of the chemicals 202 from the processing chamber 110 to the trapping unit 140. In some embodiments, the first valve 132 is an auto pressure control (APC) valve.

In some embodiments, the trapping unit 140 is disposed inside the exhaust conduit 131 and between the first end 131a and the second end 131b of the exhaust conduit 131. In some embodiments, the trapping unit 140 is disposed between the first valve 132 and the pump 150.

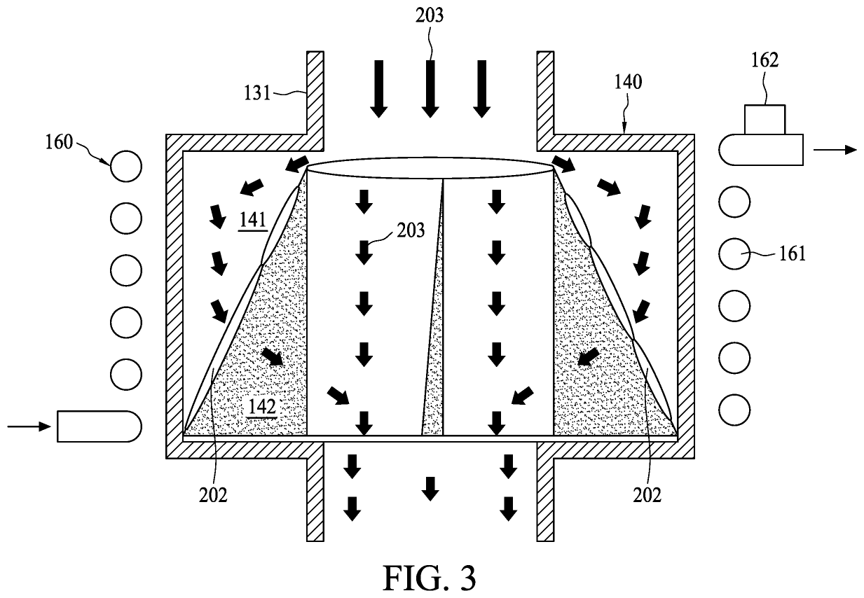

FIG. 3 is a schematic cross-sectional view of a portion of the apparatus 100 for manufacturing a semiconductor structure shown in FIG. 1 in accordance with some embodiments of the present disclosure. Referring to FIGS. 1 and 3, in some embodiments, the trapping unit 140 collects the chemicals 202 flowing from the processing chamber 110 through the exhaust conduit 131, while the residual gas 203 from the processing chamber 110 passes through the trapping unit 140. In some embodiments, the chemicals 202 accumulate in the trapping unit 140, and the trapping unit 140 needs to be replaced with a new trapping unit 140 when an excessive amount of chemicals 202 accumulate in the trapping unit 140 and block the residual gas 203 from easily passing through the trapping unit 140.

In some embodiments, the trapping unit 140 includes a trapping chamber 141 and a trapping component 142 disposed in the trapping chamber 141, wherein the trapping component 142 is configured to trap the chemicals 202 in the trapping chamber 141. In some embodiments, a greater surface area of the trapping component 142 corresponds to a greater amount of the chemicals 202 collected by the trapping unit 140. In some embodiments, the trapping component 142 includes metal. In some embodiments, the trapping component 142 is acid resistant.

In some embodiments, the cooling system 160 is disposed adjacent to the trapping unit 140 and is configured to cool the trapping unit 140. In some embodiments, the cooling system 160 surrounds the trapping unit 140. In some embodiments, the cooling system 160 includes a coolant conduit 161 configured to allow a coolant (not shown) to flow through. The coolant may increase an efficiency of heat dissipation. In some embodiments, the coolant conduit 161 surrounds the trapping unit 140.

In some embodiments, the cooling system 160 includes a coolant sensor 162 configured to sense a temperature of the coolant conduit 161 and a flow rate of the coolant flowing through the coolant conduit 161. In some embodiments, the coolant sensor 162 functions to provide information to the control system 170, and the central processor 171 of the control system 170 derives an estimated timing of replacing the trapping unit 140 based on the information. In some embodiments, the information includes the temperature of the coolant conduit 161 and the flow rate of the coolant flowing through the coolant conduit 161.

In some embodiments, the pump 150 is disposed at the second end 131b of the exhaust conduit 131 and is configured to suck the chemicals 202 and the residual gas 203 through the exhaust conduit 131. In some embodiments, the pump 150 is coupled to the exhaust conduit 131, and the trapping unit 140 is disposed between the processing chamber 110 and the pump 150. In some embodiments, the pump 150 is configured to suck the chemicals 202 (if any) and the residual gas 203 out of the exhaust conduit 131. In some embodiments, the pump 150 is a vacuum pump 150.

In some embodiments, the chemicals 202 that are not trapped by the trapping unit 140 may accumulate in the pump 150, and when there is an excessive amount of the chemicals 202 in the pump 150, the pump 150 will malfunction and shut down. In other word, if the trapping unit 140 traps all the chemicals 202, the pump 150 may not be shut down due to the contamination of the chemicals 202 accumulating in the pump 150.

In some embodiments, while the pump 150 is operating, the first valve 132 may, while open, allow the pump 150 to draw the chemicals 202 and the residual gas 203 from the processing chamber 110, and the first valve 132 may, while closed, prevent the pump 150 from drawing the chemicals 202 and the residual gas 203 from the processing chamber 110. In some embodiments, while the pump 150 is operating, a pressure in the processing chamber 110 is adjusted by regulating a degree of valve opening of the first valve 132. That is, while the pump 150 is operating, the degree of opening of the first valve 132 may be adjusted based on a pressure information detected by the sensor 172, and thereby an actual pressure in the processing chamber 110 can be controlled to be closer to a predetermined set pressure. As a result, an exhaust capacity of the exhaust conduit 131 is adjustable, and the actual pressure in the processing chamber 110 gradually becomes closer to the predetermined set pressure.

In some embodiments, a second valve 133 is disposed between the trapping unit 140 and the pump 150. In some embodiments, when the first valve 132 and the second valve 133 are both in an open configuration, the processing chamber 110 is vacuum-exhausted by the pump 150, and the chemicals 202 and the residual gas 203 remaining in the processing chamber 110 are discharged from the processing chamber 110 after being used in the formation of the semiconductor structure 201.

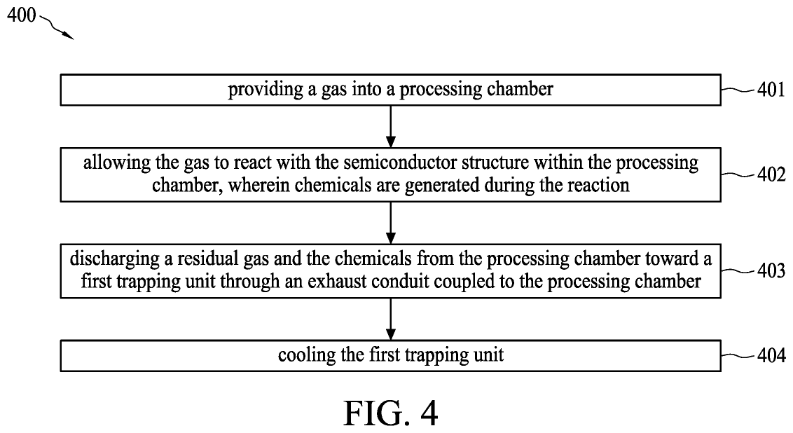

According to some embodiments of the present disclosure, a method for manufacturing a semiconductor structure is disclosed. In some embodiments, the method 400 utilizes an apparatus 100 for manufacturing a semiconductor structure. The method 400 includes a number of operations, and the description and illustration are not deemed as a limitation to the sequence of operations. FIG. 4 is a flowchart of the method 400 in accordance with some embodiments. The method 400 includes a number of operations (401 to 404). Additional steps can be provided before, during, and after the steps shown in FIG. 4, and some of the steps described below can be replaced or eliminated in other embodiments of the method 400. The order of the steps may be interchangeable.

In operation 401, referring to FIG. 4, a gas is provided into a processing chamber. In operation 402, the gas reacts with a semiconductor structure within the processing chamber, wherein chemicals are generated during the reaction. In operation 403, a residual gas and the chemicals are discharged from the processing chamber toward a first trapping unit through an exhaust conduit coupled to the processing chamber. In operation 404, the first trapping unit is cooled.

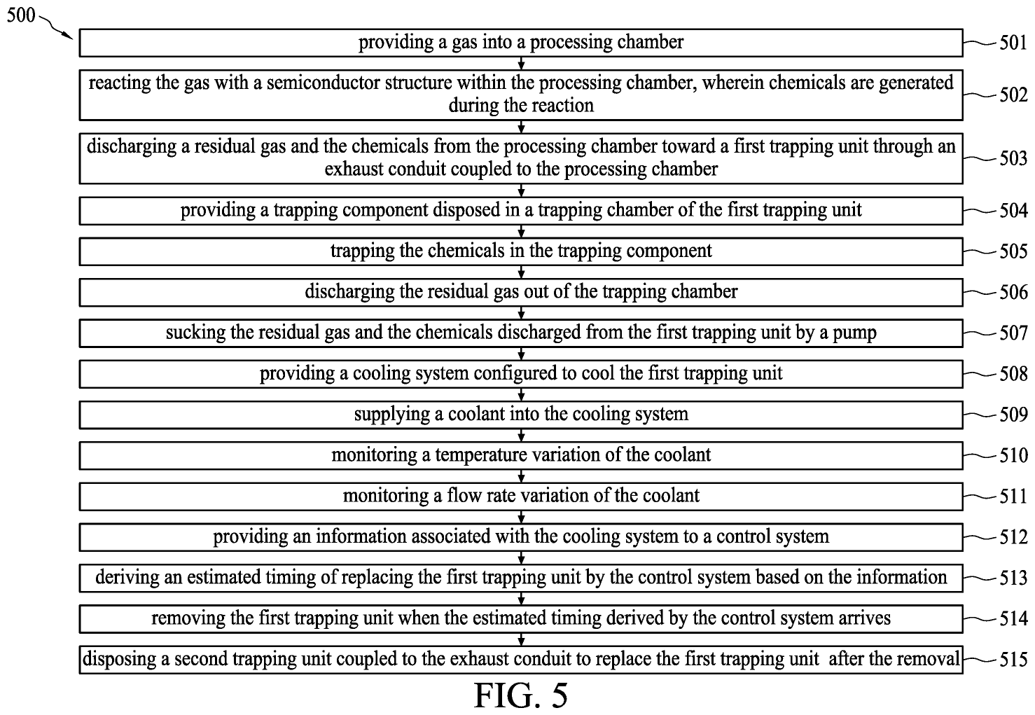

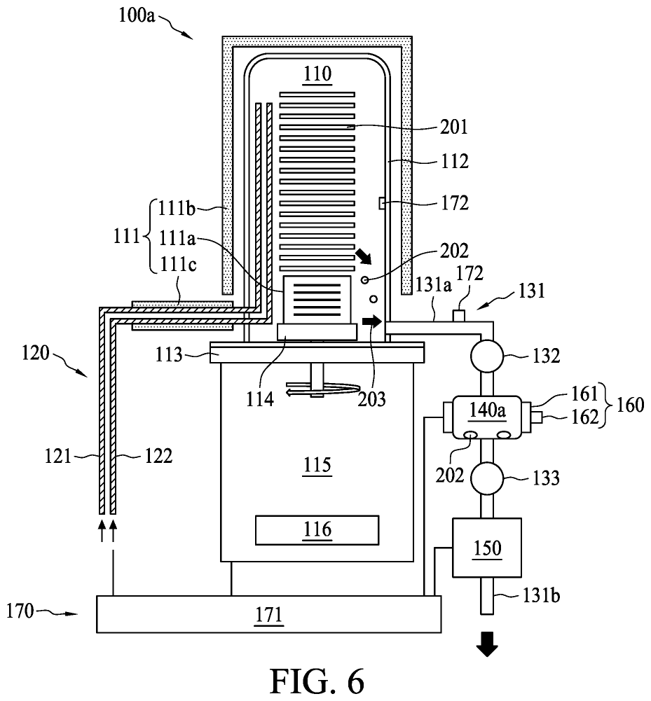

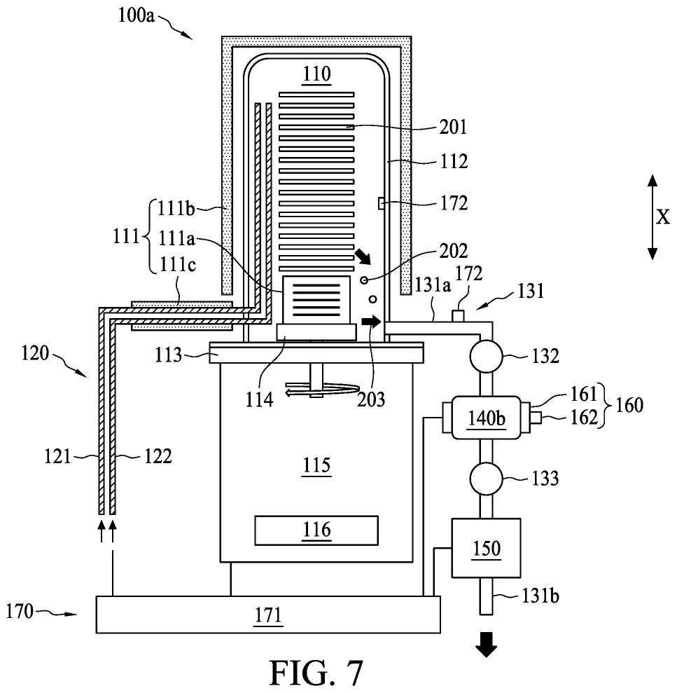

According to some embodiments of the present disclosure, another method for manufacturing a semiconductor structure is disclosed. In some embodiments, the method 500 utilizes an apparatus 100 for manufacturing a semiconductor structure. The method 500 includes a number of operations, and the description and illustration are not deemed as a limitation to the sequence of operations. FIG. 5 is a flowchart of the method 500 in accordance with some embodiments. The method 500 includes a number of operations (501 to 515). Additional steps can be provided before, during, and after the steps shown in FIG. 5, and some of the steps described below can be replaced or eliminated in other embodiments of the method 500. The order of the steps may be interchangeable. FIGS. 6 to 7 are schematic views of one or more operations of the method 500 for manufacturing a semiconductor structure in accordance with some embodiments of the present disclosure.

The method 500 begins with operation 501, in which a gas is provided into a processing chamber 110. In some embodiments, operation 501 of the method 500 is similar to operation 401 of the method 400.

In some embodiments, an apparatus 100a shown in FIG. 6 is provided. In some embodiments, referring to FIG. 6, the apparatus 100a provided to perform the method 500 is similar to the apparatus 100 shown in FIG. 1, and the apparatus 100a includes a first trapping unit 140a. In some embodiments, the first trapping unit 140a is disposed inside an exhaust conduit 131, between a first end 131a and a second end 131b of the exhaust conduit 131, and the first trapping unit 140a is configured to collect chemicals 202 discharged from the processing chamber 110 through the exhaust conduit 131. In some embodiments, the first trapping unit 140a shown in FIG. 6 is similar to the trapping unit 140 shown in FIG. 1.

In some embodiments, the gas includes a first gas, such as a source gas, and a second gas, such as a reaction gas. In some embodiments, the first gas and the second gas are pumped into the processing chamber 110 from a gas supply system 120 in communication with the processing chamber 110. In some embodiments, a first gas conduit 121 provides the first gas into the processing chamber 110. In some embodiments, a second gas conduit 122 provides the second gas into the processing chamber 110. In some embodiments, the first and second gases are heated. In some embodiments, a third heater 111c heats the gases before the gases are provided into the processing chamber 110.

The method 500 continues with operation 502, in which the gas reacts with a semiconductor structure 201 within the processing chamber 110, wherein chemicals 202 are generated during the reaction. In some embodiments, operation 502 of the method 500 is similar to operation 402 of the method 400.

In some embodiments, a film (not shown) is formed on the semiconductor structure 201 after the reaction. In some embodiments, a residual gas 203 and the chemicals 202 are generated in the processing chamber 110 when the first gas and the second gas react with the semiconductor structure 201. In some embodiments, the residual gas 203 includes unreacted first gas, unreacted second gas, and nitrogen gas.

In some embodiments, the semiconductor structure 201 is heated in the processing chamber 110 by a heating system 111. In some embodiments, a first heater 111a disposed under the semiconductor structures 201 heats the semiconductor structures 201. In some embodiments, a second heater 111b disposed adjacent to the processing chamber 110 heats the semiconductor structures 201.

The method 500 continues with operation 503, in which the chemicals 202 and the residual gas 203 are discharged from the processing chamber 110 toward a first trapping unit 140a through an exhaust conduit 131 coupled to the processing chamber 110. In some embodiments, operation 502 and operation 503 are performed simultaneously. In some embodiments, operation 503 of the method 500 is similar to operation 403 of the method 400.

In some embodiments, a first valve 132 disposed between the processing chamber 110 and the first trapping unit 140a is provided. In some embodiments, the first valve 132 is in an open configuration to allow the chemicals 202 and the residual gas 203 to flow from the processing chamber 110 toward a first trapping unit 140a through the exhaust conduit 131.

The method 500 continues with operation 504, in which a trapping component 142 disposed in a trapping chamber 141 of the first trapping unit 140a is provided. In some embodiments, the first trapping unit 140a includes the trapping chamber 141 and the trapping component 142 disposed in the trapping chamber 141 and configured to trap the chemicals 202 in the trapping chamber 141. In some embodiments, a configuration of the first trapping unit 140a is similar to a configuration of the trapping unit 140 shown in FIG. 3.

The method 500 continues with operation 505. Operation 505 includes trapping the chemicals 202 in the trapping component 142. The method 500 continues with operation 506, in which the residual gas 203 is discharged out of the trapping chamber 141. In some embodiments, operation 505 and operation 506 are performed simultaneously.

In some embodiments, the chemicals 202 and the residual gas 203 discharged from the processing chamber 110, flowed toward and entered the first trapping unit 140a through the exhaust conduit 131. In some embodiments, the trapping component 142 traps the chemicals 202 in the first trapping unit 140a, and the residual gas 203 passes through the first trapping unit 140a. In some embodiments, a portion of the chemicals 202 are trapped by the first trapping unit 140a, and a remainder of the chemicals 202 pass through the first trapping unit 140a and flow with the residual gas 203.

The method 500 continues with operation 507, in which the chemicals 202 and the residual gas 203 discharged from the first trapping unit 140a are sucked by a pump 150. In some embodiments, the pump 150 draws the residual gas 203 out of the exhaust conduit 131, and the chemicals 202 discharged from the first trapping unit 140a may remain in the pump 150 and cause the pump 150 to shut down. In some embodiments, all of the chemicals 202 are trapped by the first trapping unit 140a, and no chemicals 202 are discharged from the first trapping unit 140a and allowed to flow into the pump 150. In some embodiments, a second valve 133 disposed between the first trapping unit 140a and the pump 150 is provided. In some embodiments, operation 505 to operation 507 are performed simultaneously.

The method 500 continues with operation 508. Operation 508 includes providing a cooling system 160 configured to cool the first trapping unit 140a. In some embodiments, the first trapping unit 140a is surrounded by the cooling system 160. In some embodiments, operation 508 of the method 500 is similar to operation 404 of the method 400. In some embodiments, the cooling system 160 cools the first trapping unit 140a while the first trapping unit 140a continues trapping the chemicals 202 and discharging the residual gas 203 out of the first trapping unit 140a.

The method 500 continues with operation 509, in which a coolant is supplied into the cooling system 160. In some embodiments, the coolant is supplied into a coolant conduit 161 configured to allow a coolant to flow therethrough. In some embodiments, a coolant sensor 162 configured to sense a temperature of the coolant conduit 161 and a flow rate of the coolant flowing through the coolant conduit 161 is provided.

The method 500 continues with operation 510, in which a temperature variation of the coolant is monitored. In some embodiments, the temperature variation of the coolant is monitored continuously. The method 500 continues with operation 511, in which a flow rate variation of the coolant is monitored. In some embodiments, the flow rate variation of the coolant is monitored continuously. In some embodiments, operation 510 and operation 511 are performed simultaneously. In some embodiments, the coolant sensor 162 senses the temperature variation of the coolant and the flow rate variation of the coolant. In some embodiments, operation 509 to operation 511 are performed simultaneously.

The method 500 continues with operation 512, in which an information associated with the cooling system 160 is provided to a control system 170. In some embodiments, the coolant sensor 162 provides the information associated with the cooling system 160 to the control system 170. In some embodiments, the information provided by the coolant sensor 162 includes the temperature variation of the coolant and the flow rate variation of the coolant.

The method 500 continues with operation 513, in which an estimated timing of replacing the first trapping unit 140a is derived by the control system 170 based on the information. The first trapping unit 140a may function normally until the estimated timing arrives. As time gets closer to the estimated timing, more chemicals 202 are trapped in the first trapping unit 140a. When the estimated timing derived by the control system 170 is overdue, the chemicals 202 trapped in the first trapping unit 140a may further block the exhaust conduit 131, the residual gas 203 may not pass through the first unit 140a due to the blockage of the chemicals 202, and the pressure of the processing chamber 110 may increase to an undesired pressure and become greater than a predetermined pressure.

The method 500 continues with operation 514. Operation 514 includes removing the first trapping unit 140a when the estimated timing derived by the control system 170 arrives. In some embodiments, the removal is performed when the pressure inside the processing chamber 110 is less than the predetermined pressure. In some embodiments, the first valve 132 is closed before the removal of the first trapping unit 140a to stop the chemicals 202 and the residual gas 203 from discharging from the processing chamber 110 toward the first trapping unit 140a through the exhaust conduit 131. In some embodiments, the second valve 133 is closed before the removal of the first trapping unit 140a. In some embodiments, the apparatus 100 continues to manufacture the semiconductor structure 201 while the removal is performed.

The method 500 continues with operation 515. Operation 515 includes disposing a second trapping unit 140b coupled to the exhaust conduit 131 to replace the first trapping unit 140a after the removal. In some embodiments, referring to FIG. 7, configurations of the second trapping unit 140b are similar to those of the first trapping unit 140b. In some embodiments, the second trapping unit 140b has no chemicals 202 disposed therein. In some embodiments, the apparatus 100 continues to manufacture the semiconductor structure 201 while the operation 515 is performed.

In some embodiments, the first valve 132 is switched to an open configuration after the second trapping unit 140b is coupled to the exhaust conduit 131. In some embodiments, the first valve 132 is in an open configuration to allow the chemicals 202 and the residual gas 203 to flow from the processing chamber 110 toward the second trapping unit 140b through the exhaust conduit 131. In some embodiments, the second valve 133 is switched to an open configuration after the second trapping unit 140b is coupled to the exhaust conduit 131. In some embodiments, the second valve 133 is in an open configuration to allow the residual gas 203 to flow from the second trapping unit 140b toward the pump 150 through the exhaust conduit 131.

In some embodiments, the cooling system 160 is configured to cool the second trapping unit 140b. In some embodiments, the coolant is provided into the cooling system 160 surrounding the second trapping unit 140b, and the control system 170 and the coolant sensor 162 monitors the cooling system 160. In some embodiments, an information associated with the cooling system 160 surrounding the second trapping unit 140b is provided to the control system 170, and the control system 170 derives an estimated timing of replacing the second trapping unit 140b based on the information.

In accordance with some embodiments of the disclosure, an apparatus for manufacturing a semiconductor structure includes a processing chamber configured to form a film on the semiconductor structure; a gas supply system in communication with the processing chamber; an exhaust conduit having a first end coupled to the processing chamber and a second end distal to the processing chamber; a trapping unit disposed inside the exhaust conduit, between the first end and the second end, and configured to collect chemicals flowing from the processing chamber through the exhaust conduit; a cooling system disposed adjacent to the trapping unit and configured to cool the trapping unit; and a pump disposed at the second end of the exhaust conduit and configured to suck the chemicals inside the exhaust conduit.

In some embodiments, the apparatus further includes a control system configured to control the gas supply system and the cooling system. In some embodiments, the cooling system has a sensor for providing information to the control system, and the control system is configured to derive an estimated timing of replacing the trapping unit based on the information. In some embodiments, the apparatus further includes a valve disposed inside the exhaust conduit and between the processing chamber and the trapping unit. In some embodiments, the valve is an auto-pressure-control valve. In some embodiments, the cooling system includes a coolant conduit configured to allow a coolant to flow through, and a sensor configured to sense a temperature of the coolant conduit and a flow rate of the coolant flowing through the coolant conduit. In some embodiments, the cooling system surrounds the trapping unit. In some embodiments, the trapping unit includes a trapping chamber and a trapping component disposed in the trapping chamber and configured to trap the chemicals in the trapping chamber.

In accordance with some embodiments of the disclosure, an apparatus for manufacturing a semiconductor structure includes a trapping unit configured to collect chemicals discharged from a processing chamber; a cooling system disposed adjacent to the trapping unit and configured to cool the trapping unit; and a control system electrically connected to cooling system, wherein the cooling system has a sensor for providing information to the control system, and the control system derives an estimated timing of replacing the trapping unit based on the information.

In some embodiments, the apparatus further includes a valve disposed between the trapping unit and the processing chamber and configured to control a flow of the chemicals discharged from the processing chamber to the trapping unit. In some embodiments, the apparatus is configured to form a film over the semiconductor structure by an atomic layer deposition (ALD). In some embodiments, the cooling system further includes a coolant conduit surrounding the trapping unit.

In accordance with some embodiments of the disclosure, a method for manufacturing a semiconductor structure includes providing a gas into a processing chamber; allowing the gas to react with the semiconductor structure within the processing chamber, wherein chemicals are generated during the reaction; discharging a residual gas and the chemicals from the processing chamber toward a first trapping unit through an exhaust conduit coupled to the processing chamber; and cooling the first trapping unit.

In some embodiments, the method further includes providing a coolant into a cooling system configured to cool the first trapping unit; monitoring a temperature variation of the coolant; and monitoring a flow rate variation of the coolant. In some embodiments, the method further includes providing the cooling system configured to cool the first trapping unit; providing information associated with the cooling system to a control system; deriving an estimated timing of replacing the first trapping unit by the control system based on the information; and removing the first trapping unit when the estimated timing derived by the control system arrives.

In some embodiments, the method further includes disposing a second trapping unit coupled to the exhaust conduit to replace the first trapping unit after the removal. In some embodiments, the removal is performed when a pressure inside the processing chamber is less than a predetermined pressure. In some embodiments, the method further includes providing a trapping component disposed in a trapping chamber of the first trapping unit; trapping the chemicals in the trapping component; and discharging the residual gas out of the trapping chamber.

In some embodiments, the method further includes sucking the residual gas and the chemicals discharged from the first trapping unit by a pump, wherein the pump is coupled to the exhaust conduit, and the first trapping unit is disposed between the processing chamber and the pump. In some embodiments, the method further includes providing a valve disposed between the processing chamber and the first trapping unit; and closing the valve before the removal of the first trapping unit.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An apparatus for manufacturing a semiconductor structure, comprising:
a processing chamber configured to form a film on the semiconductor structure;
a gas supply system in communication with the processing chamber;
an exhaust conduit having a first end coupled to the processing chamber and a second end distal to the processing chamber;
a trapping unit disposed inside the exhaust conduit, between the first end and the second end, and configured to collect chemicals flowing from the processing chamber through the exhaust conduit;
a cooling system disposed adjacent to the trapping unit and configured to cool the trapping unit; and
a pump disposed at the second end of the exhaust conduit and configured to suck the chemicals inside the exhaust conduit.

2. The apparatus of claim 1, further comprising a control system configured to control the gas supply system and the cooling system.

3. The apparatus of claim 2, wherein the cooling system has a sensor for providing information to the control system, and the control system is configured to derive an estimated timing of replacing the trapping unit based on the information.

4. The apparatus of claim 1, further comprising a valve disposed inside the exhaust conduit and between the processing chamber and the trapping unit.

5. The apparatus of claim 4, wherein the valve is an auto-pressure-control valve.

6. The apparatus of claim 1, wherein the cooling system includes a coolant conduit configured to allow a coolant to flow therethrough, and a sensor configured to sense a temperature of the coolant conduit and a flow rate of the coolant flowing through the coolant conduit.

7. The apparatus of claim 1, wherein the cooling system surrounds the trapping unit.

8. The apparatus of claim 1, wherein the trapping unit includes a trapping chamber and a trapping component disposed in the trapping chamber and configured to trap the chemicals in the trapping chamber.

9. An apparatus for manufacturing a semiconductor structure, comprising:
a trapping unit configured to collect chemicals discharged from a processing chamber;
a cooling system disposed adjacent to the trapping unit and configured to cool the trapping unit; and
a control system electrically connected to cooling system,
wherein the cooling system has a sensor for providing information to the control system, and the control system derives an estimated timing of replacing the trapping unit based on the information.

10. The apparatus of claim 9, further comprising a valve disposed between the trapping unit and the processing chamber and configured to control a flow of the chemicals flowing from the processing chamber to the trapping unit.

11. The apparatus of claim 9, wherein the apparatus is configured to form a film over the semiconductor structure by an atomic layer deposition (ALD).

12. The apparatus of claim 9, wherein the cooling system further includes a coolant conduit surrounding the trapping unit.

13. A method for manufacturing a semiconductor structure, comprising:
providing a gas into a processing chamber;
allowing the gas to react with the semiconductor structure within the processing chamber, wherein chemicals are generated during the reaction;
discharging a residual gas and the chemicals from the processing chamber toward a first trapping unit through an exhaust conduit coupled to the processing chamber; and
cooling the first trapping unit.

14. The method of claim 13, further comprising:
providing a coolant into a cooling system configured to cool the first trapping unit;
monitoring a temperature variation of the coolant; and
monitoring a flow rate variation of the coolant.

15. The method of claim 13, further comprising:
providing a cooling system configured to cool the first trapping unit;
providing information associated with the cooling system to a control system;
deriving an estimated timing of replacing the first trapping unit by the control system based on the information; and
removing the first trapping unit when the estimated timing derived by the control system arrives.

16. The method of claim 15, further comprising disposing a second trapping unit coupled to the exhaust conduit to replace the first trapping unit after the removal.

17. The method of claim 15, wherein the removal is performed when a pressure inside the processing chamber is less than a predetermined pressure.

18. The method of claim 13, further comprising:
providing a trapping component disposed in a trapping chamber of the first trapping unit;
trapping the chemicals in the trapping component; and
discharging the residual gas out of the trapping chamber.

19. The method of claim 13, further comprising:
sucking the residual gas and the chemicals from the first trapping unit by a pump,
wherein the pump is coupled to the exhaust conduit, and the first trapping unit is disposed between the processing chamber and the pump.

20. The method of claim 15, further comprising:
providing a valve disposed between the processing chamber and the first trapping unit; and
closing the valve before the removal of the first trapping unit.
